(19) United States
(12) Patent Application Publication
(10) Pub. No.: US 2026/0088810 A1
(43) Pub. Date: Mar. 26, 2026

(54) VOLTAGE COMPARATOR CIRCUIT WITH OFFSET CORRECTION

(71) Applicant: TAIWAN SEMICONDUCTOR MANUFACTURING COMPANY, LTD., Hsinchu (TW)

(72) Inventors: Tomohiko YANO, Hsinchu (TW); Perng-Fei YUH, Hsinchu (TW)

(21) Appl. No.: 18/897,932

(22) Filed: Sep. 26, 2024

(51) Int. Cl. H03K 5/24

(52) U.S. Cl. CPC H03K 5/249

(57) ABSTRACT

An integrated circuit includes a first multiplexer, a second multiplexing-input, a first clocked comparator, and a second clocked comparator. A first input node is connected to a first multiplexing-input of the first multiplexer, a first multiplexing-input of the second multiplexer, a first comparing-input of the first clocked comparator, and a first comparing-input of the second clocked comparator. A second input node is connected to a second multiplexing-input of the first multiplexer and a second multiplexing-input of the second multiplexer. An output of the first multiplexer is connected to second comparing-input of the first clocked comparator, and an output of the second multiplexer is connected to a second comparing-input of the second clocked comparator. The integrated circuit also includes an offset control circuit connected to a comparator-output of the first clocked comparator and a comparator-output of the second clocked comparator.

### BACKGROUND

The recent trend in miniaturizing integrated circuits (ICs) has resulted in smaller devices which consume less power yet provide more functionality at higher speeds. The miniaturization process has also resulted in stricter design and manufacturing specifications as well as reliability challenges. Various electronic design automation (EDA) tools generate, optimize and verify standard cell layout designs for integrated circuits while ensuring that the standard cell layout design and manufacturing specifications are met.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of a voltage comparator circuit having corrections for background offsets, in accordance with some embodiments.

FIG. 2 is a circuit diagram of a clocked comparator operable to receive an offset trim code for trimming an input offset, in accordance with some embodiments.

FIGS. 3A-3B are circuit diagrams of a variable capacitor implemented with an array of capacitors, in accordance with some embodiments.

FIG. 4 is a timing diagram of the operation of the voltage comparator circuit in FIG. 1, in accordance with some embodiments.

FIG. 5 is a flowchart of method of operating a voltage comparator circuit, in accordance with some embodiments.

FIG. 6A is a circuit diagram of a charge pump having a voltage comparator circuit which has the input offset trimmed during operation, in accordance with some embodiments.

FIG. 6B is a circuit diagram of a digital low dropout (LDO) voltage regulator having a voltage comparator circuit which has the input offset trimmed during operation, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “bencath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, a voltage comparator circuit having corrections for input offsets includes a first input node configured to carry a first voltage signal, and a second input node configured to carry a second voltage signal. The voltage comparator circuit also includes a first multiplexer and a second multiplexer. Each of the first multiplexer and the second multiplexer has a first multiplexing-input configured to receive the first voltage signal from the first input node and has a second multiplexing-input configured to receive the second voltage signal from the second input node. The voltage comparator circuit further includes a first clocked comparator and a second clocked comparator. Each of the first clocked comparator and the second clocked comparator has a first comparing-input configured to receive the first voltage signal from the first input node. The first clocked comparator has a second comparing-input configured to receive the second voltage signal from the first multiplexer during a first time period and configured to receive the first voltage signal from the first multiplexer during a second time period. The second clocked comparator has a second comparing-input configured to receive the first voltage signal from the second multiplexer during the first time period and configured to receive the second voltage signal from the second multiplexer during the second time period.

During a first time period, the first clocked comparator operates in the comparison mode to compare the voltages received from the input nodes, while the second clocked comparator operates in the calibration mode to trim the input offsets. During a second time period, the second clocked comparator operates in the comparison mode to compare the voltages received from the input nodes, while the first clocked comparator operates in the calibration mode to trim the input offsets. The voltage comparator circuit is operable with the 100% duty cycle to compare the voltages received from the first input node and from the second input node, with reduced input offsets. Charge pumps or digital low dropout voltage regulators implemented with the voltage comparator circuit having corrections for input offsets as described in this disclosure have improved performance as compared with alternative implementations in which voltage comparator circuits do not have 100% duty cycle.

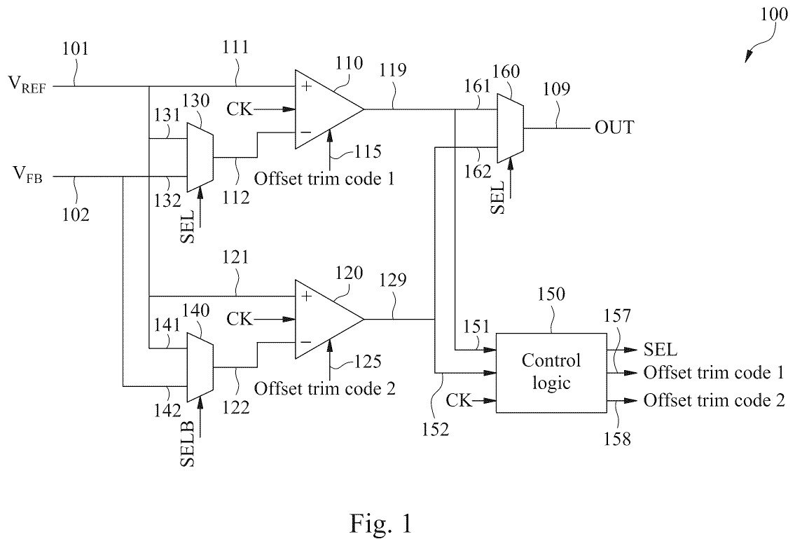

FIG. 1 is a circuit diagram of a voltage comparator circuit 100 having corrections for background offsets, in accordance with some embodiments. In FIG. 1, the voltage comparator circuit 100 includes clocked comparators 110-120, multiplexers 130-140 and 160, and an offset control circuit 150. A first input node 101, which is configured to receive a first voltage signal (such as V_{REF}), is connected to both a first comparing-input 111 of the clocked comparator 110 and a first comparing-input 121 of the clocked comparator 120. The first input node 101 is also connected to both a first multiplexing-input 131 of the multiplexer 130 and a first multiplexing-input 141 of the multiplexer 140. A second input node 102, which is configured to receive a second voltage signal (such as V_{FB}), is connected to both a second multiplexing-input 132 of the multiplexer 130 and a second multiplexing-input 142 of the multiplexer 140. The output of the multiplexer 130 is connected to a second comparing-input 112 of the clocked comparator 110, and the output of the multiplexer 140 is connected to a second comparing-input 122 of the clocked comparator 120.

The clocked comparator 110 has a comparator-output 119 connected to a first multiplexing-input 161 of the multiplexer 160, and the clocked comparator 120 has a comparator-output 129 connected to a second multiplexing-input 162 of the multiplexer 160. Furthermore, the comparator-output 119 of the clocked comparator 110 and the comparator-output 129 of the clocked comparator 120 are also coupled to the offset control circuit 150. The offset trim codes generated by the offset control circuit 150 are coupled to the offset-trim input 115 of the clocked comparator 110 and the offset-trim input 125 of the clocked comparator 120. In addition, each of the offset control circuit 150 and the clocked comparator 110 and 120 is synchronized with a common clock signal, such as the clock signal CK. Each of the multiplexers 130-140 and 160 is controlled with a corresponding selection signal. In one specific implementation, the selection signal for controlling the multiplexer 130 is a logic signal SEL, the selection signal for controlling the multiplexer 140 is a logic signal SELB which is a logical complement of the logic signal SEL, and the selection signal for controlling the multiplexer 160 is also the logic signal SEL.

In operation, one of the clocked comparators 110 and 120 is in a comparison mode, while the other one of the clocked comparators 110 and 120 is in a calibration mode. Each of the clocked comparators 110 and 120 operates alternatively between the comparison mode and the calibration mode. For example, during a first time period, the clocked comparator 110 is in the comparison mode while the clocked comparator 120 is in the calibration mode. Subsequently, during a second time period, the clocked comparator 110 is in the calibration mode while the clocked comparator 120 is in the comparison mode.

When the clocked comparator 110 is in the comparison mode, the first voltage signal (such as V_{REF}) at the first input node 101 is transmitted to the first comparing-input 111 of the clocked comparator 110, while the second voltage signal (such as V_{FB}) at the second input node 102 is transmitted to the second comparing-input 112 of the clocked comparator 110 through the multiplexer 130. In addition, an output voltage at the comparator-output 119 of the clocked comparator 110 is transmitted (through the multiplexer 160) to an output node 109 of the voltage comparator circuit 100.

When the clocked comparator 110 is in the calibration mode, the first voltage signal (such as V_{REF}) is transmitted to both the first comparing-input 111 and the second comparing-input 112 of the clocked comparator 110. Specifically, from the first input node 101, the first voltage signal is transmitted to the first comparing-input 111 directly but transmitted to the second comparing-input 112 through the multiplexer 130. Even though the same voltage signal is transmitted to the two comparing-inputs (i.e., 111 and 112) of the clocked comparator 110, the operation of the clocked comparator 110 is still subject to the influence of an input offset V1_{offset}. The output voltage at the comparator-output 119 of the clocked comparator 110 depends upon the input offset V1_{offset}.

When the clocked comparator 120 is in the comparison mode, the first voltage signal (such as V_{REF}) at the first input node 101 is transmitted to the first comparing-input 121 of the clocked comparator 120, while the second voltage signal (such as V_{FB}) at the second input node 102 is transmitted to the second comparing-input 122 of the clocked comparator 120 through the multiplexer 140. In addition, an output voltage at the comparator-output 129 of the clocked comparator 120 is transmitted (through the multiplexer 160) to an output node 109 of the voltage comparator circuit 100.

When the clocked comparator 120 is in the calibration mode, the first voltage signal (such as V_{REF}) is transmitted to both the first comparing-input 121 and the second comparing-input 122 of the clocked comparator 120. Specifically, from the first input node 101, the first voltage signal is transmitted to the first comparing-input 121 directly but transmitted to the second comparing-input 122 through the multiplexer 140. Even though the same voltage signal is transmitted to the two comparing-inputs (i.e., 121 and 122) of the clocked comparator 120, the operation of the clocked comparator 120 is still subject to the influence of an input offset V2_{offset}. The output voltage at the comparator-output 129 of the clocked comparator 120 depends upon the input offset V2_{offset}.

During the operation that the clocked comparator 110 is in the comparison mode, the input offset V1_{offset} practically shifts the effective threshold voltage of the clocked comparator 110. For example, in one implementation, the clocked comparator 110 is implemented with one threshold voltage V1ₜₕ. During the comparison operation, as the voltage signals V_{REF} and V_{FB} are correspondingly transmitted to the two comparing-inputs 111 and 112, the voltage difference V_{REF}−V_{FB}+V1_{offset} is compared with the threshold voltage V1ₜₕ of the clocked comparator 110. Consequently, the output voltage at the comparator-output 119 depends upon whether the voltage difference V_{REF}−V_{FB} is larger than or smaller than the effective threshold voltage V1ₜₕ−V1_{offset}. In another implementation, the clocked comparator 110 is implemented with an upper threshold voltage

$$V {1}_{th}^{+}$$

and a lower threshold voltage

$$V {1}_{th}^{-}$$

to support hysteresis (which is similar to the hysteresis in a Schmit trigger). During the comparison operation, as the voltage signals V_{REF} and V_{FB} are correspondingly transmitted to the two comparing-inputs 111 and 112, the voltage difference V_{REF}−V_{FB}+V1_{offset} is compared with the upper threshold voltage

$$V {1}_{th}^{+}$$

and the lower threshold voltage

$$V {1}_{th}^{-} .$$

Consequently, the output voltage at the comparator-output 119 depends upon whether the voltage difference V_{REF}−V_{FB} raises above the effective upper uresnoia vontage

$$V {1}_{th}^{+} - V {1}_{offset}$$

or whether the voltage difference V_{REF}−V_{FB} falls below the effective lower threshold voltage

$$V {1}_{th}^{-} - V {1}_{offset} .$$

During the operation that the clocked comparator 120 is in the comparison mode, the input offset V2_{offset} practically shifts the effective threshold voltage of the clocked comparator 120. For example, in one implementation, the clocked comparator 120 is implemented with one threshold voltage V2ₜₕ. During the comparison operation, as the voltage signals V_{REF} and V_{FB} are correspondingly transmitted to the two comparing-inputs 121 and 122, the voltage difference V_{REF}−V_{FB}+V2_{offset} is compared with the threshold voltage V2ₜₕ of the clocked comparator 120. Consequently, the output voltage at the comparator-output 129 depends upon whether the voltage difference V_{REF}−V_{FB} is larger than or smaller than the effective threshold voltage V2ₜₕ-V2_{offset}. In another implementation, the clocked comparator 120 is implemented with an upper threshold voltage

$${V 2}_{th}^{+}$$

and a lower threshold voltage

$${V 2}_{th}^{-}$$

to support hysteresis (which is similar to the hysteresis in a Schmit trigger). During the comparison operation, as the voltage signals V_{REF} and V_{FB} are correspondingly transmitted to the two comparing-inputs 121 and 122, the voltage difference V_{REF}−V_{FB}+V2_{offset} is compared with the upper threshold voltage

$${V 2}_{th}^{+}$$

and the lower threshold voltage

$${V 2}_{th}^{-} .$$

Consequently, the output voltage at the comparator-output 129 depends upon whether the voltage difference V_{REF}−V_{FB} raises above the effective upper threshold voltage

$${V 2}_{th}^{+} - V {2}_{offset}$$

or whether the voltage difference V_{REF}−V_{FB} falls below the effective lower threshold voltage

$${V 2}_{th}^{-} - V {2}_{offset} .$$

In the voltage comparator circuit 100 of FIG. 1, the input offset V1_{offset} of the clocked comparator 110 and the input offset V2_{offset} of the clocked comparator 120 are trimmed when operating in the calibration mode. Reducing the input offset V1_{offset} and the input offset V2_{offset} correspondingly reduces the variations of the effective threshold voltages of the clocked comparators and 110 and 120.

During the first time period while the clocked comparator 120 is in the calibration mode, an offset trim code 2 is coupled to the offset-trim input 125 of the clocked comparator 120 from an output port 158 of the offset control circuit 150, and the input offset V2_{offset} of the clocked comparator 120 is reduced with the offset trim code 2. The offset trim code 2 is generated by the offset control circuit 150 based on a voltage at the comparing-output 129 of the clocked comparator 120, as the comparing-output 129 is coupled to an input port 152 of the offset control circuit 150.

During the second time period while the clocked comparator 110 is in the calibration mode, an offset trim code 1 is coupled to the offset-trim input 115 of the clocked comparator 110 from an output port 158 of the offset control circuit 150, and the input offset V1_{offset} of the clocked comparator 110 is reduced with the offset trim code 1. The offset trim code 1 is generated by the offset control circuit 150 based on a voltage at the comparing-output 119 of the clocked comparator 110, as the comparing-output 119 is coupled to an input port 151 of the offset control circuit 150.

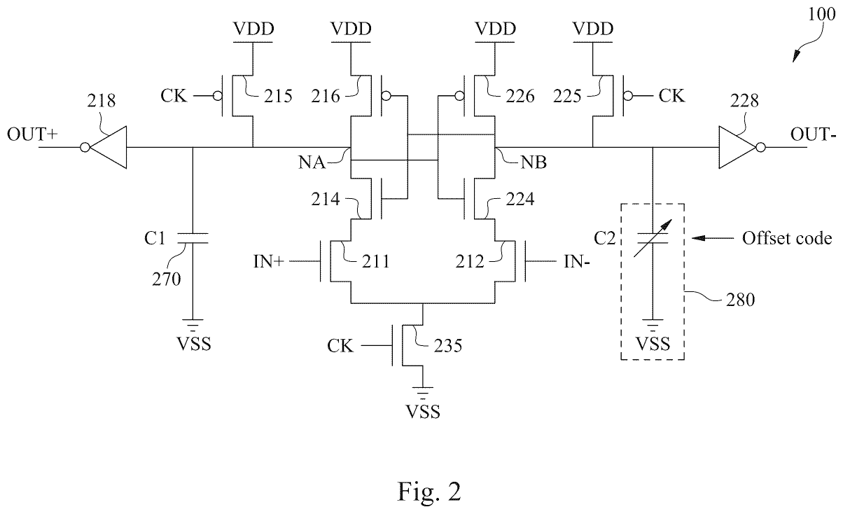

An example implementation of the clocked comparator 110 or the clocked comparator 120 is shown in FIG. 2 as a clocked comparator 200 operable to receive an offset trim code for trimming an input offset of the clocked comparator. The clocked comparator 200 includes some NMOS transistors (i.e., 211, 212, 214, 224, and 235) and some PMOS transistors (i.e., 216, 226, 215, and 225). The source terminals of the NMOS transistors 211 and 212 are connected to the drain terminal of the NMOS transistor 235, and the source terminal of the NMOS transistor 235 is connected to the supply voltage VSS.

The NMOS transistor 214 and the PMOS transistor 216 form a first inverter, while the channels of the NMOS transistor 214 and the PMOS transistor 216 are serially connected between the supply voltage VDD and the drain terminal of the NMOS transistor 211. The gate terminals of the NMOS transistor 214 and the PMOS transistor 216 are connected together as the input terminal of the first inverter. The drain terminals of the NMOS transistor 214 and the PMOS transistor 216 are connected together as the output terminal of the first inverter.

The NMOS transistor 224 and the PMOS transistor 226 form a second inverter, while the channels of the NMOS transistor 224 and the PMOS transistor 226 are serially connected between the supply voltage VDD and the drain terminal of the NMOS transistor 221. The gate terminals of the NMOS transistor 224 and the PMOS transistor 226 are connected together as the input terminal of the second inverter. The drain terminals of the NMOS transistor 224 and the PMOS transistor 226 are connected together as the output terminal of the second inverter.

Additionally, the gate terminals of the NMOS transistor 214 and the PMOS transistor 216 are connected to the drain terminals of the NMOS transistor 224 and the PMOS transistor 226 at node NB, and the gate terminals of the NMOS transistor 224 and the PMOS transistor 226 are connected to the drain terminals of the NMOS transistor 214 and the PMOS transistor 216 at node NA. Consequently, a latch circuit is formed with two cross-connected inverters: the first inverter having the NMOS transistor 214 and the PMOS transistor 216 and the second inverter having the NMOS transistor 224 and the PMOS transistor 226. The output of the first inverter at node NA is connected to the input of an inverter 218, and the output of the second inverter at node NB is connected to the input of an inverter 228.

Furthermore, the channel of the PMOS transistor 215 is connected between the supply voltage VDD and node NA, and a capacitor 270 (which includes parasitic capacitance) is connected between node NA and the supply voltage VSS. The channel of the PMOS transistor 225 is connected between the supply voltage VDD and node NB, and a variable capacitor 280 is connected between node NA and the supply voltage VSS. The variable capacitor 280 is configured to receive an offset trim code, and the capacitance of the variable capacitor 280 is adjusted based on the offset trim code. In some embodiments, the variable capacitor 280 is implemented as a capacitance bank.

In operation, the gate terminal of the NMOS transistor 211 operates as the non-inverting input of the clocked comparator 200 and receives a first voltage signal IN+, while the gate terminal of the NMOS transistor 221 operates as the inverting input of the clocked comparator 200 and receives a second voltage signal IN−. The output of the inverter 218 operates as a non-inverting output of the clocked comparator 200, and the output of the of the inverter 228 operates as an inverting output of the clocked comparator 200. The clocked comparator 200 is designed to have a nominal threshold voltage Vₜₕ=0. The clocked comparator 200, however, often has an input offset V_{offset}. Consequently, the effective threshold voltage of the clocked comparator 200 is shifted and becomes to Vₜₕ−V_{offset} (where the nominal threshold voltage Vₜₕ=0).

The gate terminals of the NMOS transistor 235 and the PMOS transistors 215 and 225 are all configured to receive the clock signal CK. When the clock signal CK is at logic LOW, the clocked comparator 200 is set to a disabled state, as the NMOS transistor 235 is driven into a non-conducting state and each of the PMOS transistors 215 and 225 is driven into a conducting state by the clock signal CK. The voltage at the output of each of the inverters 218 and 228 does not depend on the voltages at the inputs of the clocked comparator 200.

When the clock signal CK is at logic HIGH, the clocked comparator 200 is set to an enabled state, as the NMOS transistor 235 is driven into a conducting state and each of the PMOS transistors 215 and 225 is driven into a non-conducting state by the clock signal CK. In response to the clocked comparator 200 being set to the enabled state, the voltage V(OUT+) at the output of the inverter 218 and the voltage V(OUT−) at the output of the inverter 228 depend on the voltage difference V(IN+)−V (IN−) between the first voltage signal IN+ at the gate terminal of the NMOS transistor 211 and the second voltage signal IN− at the gate terminal of the NMOS transistor 221. Under the condition that the voltage difference V(IN+)−V(IN−) is larger than the effective threshold voltage Vₜₕ−V_{offset} (with Vₜₕ=0), the voltage V(OUT+) at the output of the inverter 218 becomes logic HIGH and the voltage V(OUT−) at the output of the inverter 228 becomes logic LOW. Conversely, under the condition that the voltage difference V(IN+)−V(IN−) is smaller than the effective threshold voltage Vₜₕ−V_{offset} (with Vₜₕ=0), the voltage V(OUT+) at the output of the inverter 218 becomes logic LOW and the voltage V(OUT−) at the output of the inverter 228 becomes logic HIGH.

In an ideal operation condition such that the input offset V_{offset} is trimmed to have a value of zero (i.e., V_{offset}=0), the voltage V(OUT+) at the non-inverting output of the clocked comparator 200 and the voltage V(OUT−) at the inverting output of the clocked comparator 200 depends upon whether the input voltage V(IN+) at the non-inverting input of the clocked comparator 200 is larger than or smaller than the input voltage V(IN−) at the inverting input of the clocked comparator 200. Specifically, in the scenario that the input voltage V(IN+) is larger than the input voltage V(IN−), the voltage V(OUT+) at the non-inverting output is at logic HIGH while the voltage V(OUT−) at the inverting output is at logic LOW. Conversely, in the scenario that the input voltage V(IN+) is smaller than the input voltage V(IN−), the voltage V(OUT+) at the non-inverting output is at logic LOW while the voltage V(OUT−) at the inverting output is at logic HIGH.

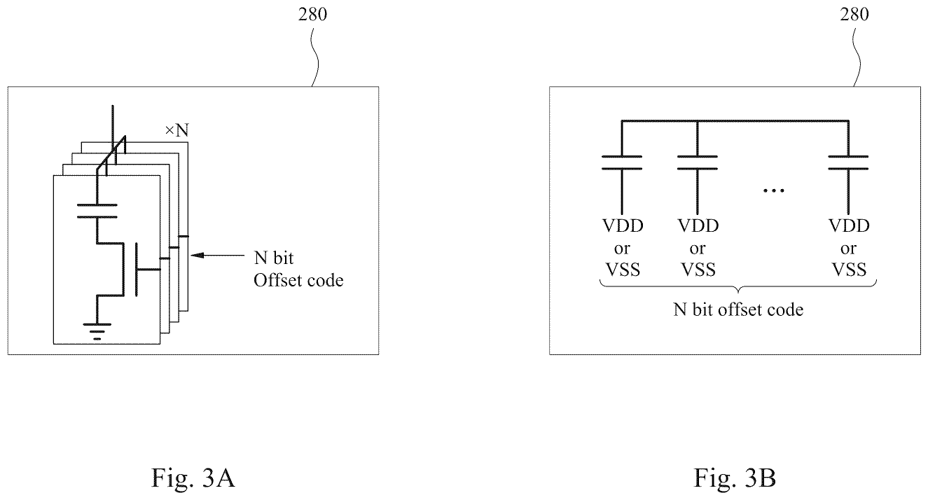

In some embodiments, if the input offset V_{offset} is not zero but has a value that is too large (e.g., the absolute value of the input offset V_{offset} is large than a predetermined value), then, the input offset V_{offset} is trimmed first in a calibration mode to reduce the absolute value of the input offset V_{offset} before the clocked comparator 200 is set to operate in a comparison mode. The input offset V_{offset} is trimmed by adjusting the capacitance of the variable capacitor 280, the capacitance of the variable capacitor 280 is adjusted based on an offset trim code received by the clocked comparator 200. Two example implementations of the variable capacitor 280 are shown in FIGS. 3A-3B.

In FIGS. 3A-3B, the variable capacitor 280 is implemented with an array of capacitors. The first terminals of all capacitors in the array of capacitors are connected together as the first terminal of the variable capacitor 280. In FIG. 3A, the second terminal of each capacitor in the array of capacitors is coupled to the supply voltage through the channel of a corresponding transistor which is either in a conducting state or a non-conducting state. For each transistor in the array of capacitors, whether the transistor is in the conducting state or in the non-conducting state is determined by the offset trim code received by the variable capacitor 280.

In FIG. 3B, the second terminal of each capacitor in the array of capacitors is connected either to the supply voltage VDD or to the supply voltage VSS. For each transistor in the array of capacitors, whether the transistor is connected to the supply voltage VDD or to the supply voltage VSS is determined by the offset trim code received by the variable capacitor 280.

In operation, the input offset V_{offset} of the clocked comparator 200 in FIG. 2 is trimmed by adjusting the capacitance of the variable capacitor 280, under the condition that the input voltage V(IN+) at the non-inverting input and the input voltage V(IN−) at the inverting input of the clocked comparator 200 are held at a same voltage. For example, in implementations that the clocked comparator 200 is used as the clocked comparator 110 or the clocked comparator 120 of the voltage comparator circuit 100 in FIG. 1, the input offset is trimmed under the condition that a same voltage signal (such as V_{REF}) is connected to both the non-inverting input and the input voltage V(IN−) in a calibration mode. After the input offset is trimmed, the clocked comparator 110 or the clocked comparator 120 is set to operate in a comparison mode.

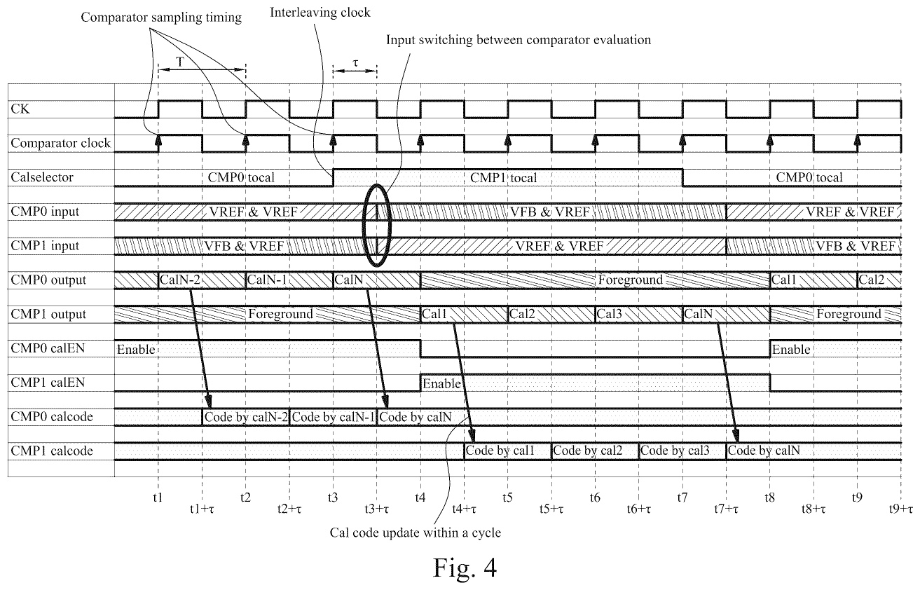

During operation, in some embodiments, each of the clocked comparator 110 and the clocked comparator 120 in FIG. 1 has the operation mode alternating between the calibration mode and the comparison mode. FIG. 4 is a timing diagram of the operation of the voltage comparator circuit 100 in FIG. 1, in accordance with some embodiments. The clock signal CK used to synchronize the operation of the voltage comparator circuit 100 has a time period T. During each time period T, the clock signal CK is at logic HIGH for a time duration τ, which corresponds to a duty cycle of τ/T. The comparator clock for driving the voltage comparator circuit 100 is generated from the clock signal CK, which in some embodiments is a mater clock of the integrated circuit containing the voltage comparator circuit 100. The operation of the voltage comparator circuit 100 is triggered by the rising edges of the comparator clock. The rising edges at time t1, t2, t3, t4, t5, t6, t7, t8, and t9 are identified in the timing diagram of FIG. 4.

The selection signals applied to the multiplexers 130-140 and 160 in the voltage comparator circuit 100 of FIG. 1 are derived from a calibration selector signal. At time t3, the calibration selector signal is changed from logic LOW to logic HIGH. At time t7, the calibration selector signal is changed from logic HIGH to logic LOW.

In response to the calibration selector signal changing from logic LOW to logic HIGH at time t3, the clocked comparator 110 is changed from the calibration mode to the comparison mode at time t3+τ, and the clocked comparator 120 is changed from the comparison mode to the calibration mode also at time t3+τ. In response to the calibration selector signal changing from logic HIGH to logic LOW at time t7, the clocked comparator 110 is changed from the comparison mode to the calibration mode at time t7+τ, and the clocked comparator 120 is changed from the calibration mode to the comparison mode also at time t7+τ.

When the clocked comparator 110 is at the calibration mode before time t3+τ or after time t7+τ, the two inputs of the clocked comparator 110 receive a same voltage signal (i.e., the voltage signals V_{REF} and V_{REF} in CMP0 input), and the output voltage at the comparator-output 119 (CMP0 output) of the clocked comparator 110 is determined by the input offset V1_{offset} of the clocked comparator 110. When the clocked comparator 110 is at the comparison mode from time t3+τ to time t7+τ, the two inputs of the clocked comparator 110 receive two different voltage signals (i.e., the voltage signals V_{REF} and V_{FB} in CMP0 input), and the output voltage at the comparator-output 119 (CMP0 output) of the clocked comparator 110 depends upon the difference V_{REF}−V_{FB}.

When the clocked comparator 120 is at the comparison mode before time t3+τ or after time t7+τ, the two inputs of the clocked comparator 120 receive two different voltage signals (i.e., the voltage signals V_{REF} and V_{FB} in CMP1 input), and the output voltage at the comparator-output 129 (CMP1 output) of the clocked comparator 120 depends upon the voltage difference V_{REF}−V_{FB}. When the clocked comparator 120 is at the calibration mode from time t3+τ to time t7+τ, the two inputs of the clocked comparator 120 receive a same voltage signal (i.e., the voltage signals V_{REF} and V_{REF} in CMP1 input), and the output voltage at the comparator-output 129 (CMP1 output) of the clocked comparator 120 is determined by the input offset V2_{offset} of the clocked comparator 120.

During the time period between time t3+τ and time t7+τ, while the clocked comparator 110 is at the comparison mode and the clocked comparator 120 is at the calibration mode, the output voltage at the comparator-output 119 (CMP0 output) of the clocked comparator 110 is transmitted to the output node 109 as a foreground signal. At time t4, the calibration enable signal CMP0 calEN for the clocked comparator 110 changes from logic HIGH to logic LOW and the calibration enable signal CMP1 calEN for the clocked comparator 120 changes from logic LOW to logic HIGH.

In response to the calibration enable signal CMP1 calEN changing to logic HIGH at time t4, the output voltage at the comparator-output 129 (CMP1 output) of the clocked comparator 120 is repetitively sampled by the offset control circuit 150. For example, the output voltage at the comparator-output 129 (CMP1 output) is sampled at time t4 as calibration signal Cal1, sampled at time t5 as calibration signal Cal2, sampled at time t6 as calibration signal Cal3, and sampled at time t7 as calibration signal CalN. For each calibration signals Cal1, Cal2, Cal3, and CalN, a corresponding offset trim code is generated by the offset control circuit 150 and coupled to the clocked comparator 120 to trim the input offset of the clocked comparator 120. Specifically, the input offset trim codes (CMP1calcode in FIG. 4) based on the calibration signals Cal1, Cal2, Cal3, and CalN are coupled to the clocked comparator 120 correspondingly between time t4+τ and time t5+τ, between time t5+τ and time t6+τ, between time t6+τ and time t7+τ, and between time t7+τ and time t8+τ.

During the time period before time t3+τ or after time t7+τ, while the clocked comparator 110 is at the calibration mode and the clocked comparator 120 is at the comparison mode, the output voltage at the comparator-output 129 (CMP1 output) of the clocked comparator 120 is transmitted to the output node 109 as a foreground signal. At time t8, the calibration enable signal CMP0 calEN for the clocked comparator 110 changes from logic LOW to logic HIGH and the calibration enable signal CMP1 calEN for the clocked comparator 120 changes from logic HIGH to logic LOW.

In response to the calibration enable signal CMP0 calEN changing to logic HIGH at time t8, the output voltage at the comparator-output 119 (CMP0 output) of the clocked comparator 110 is repetitively sampled by the offset control circuit 150. For example, the output voltage at the comparator-output 119 (CMP0 output) is sampled at time t8 as calibration signal Cal1, sampled at time t9 as calibration signal Cal2, . . . , etc. For each calibration signals Cal1, Cal2, . . . , etc., a corresponding offset trim code is generated by the offset control circuit 150 and coupled to the clocked comparator 110. For example, the input offset trim code (CMP0 calcode in FIG. 4) based on the calibration signals Cal1 is coupled to the clocked comparator 110 between time 8+T and time t9+τ to trim the input offset of the clocked comparator 110.

Similarly, before time t4, while the calibration enable signal CMP0 calEN is at logic HIGH, the output voltage at the comparator-output 119 (CMP0 output) of the clocked comparator 110 is repetitively sampled by the offset control circuit 150. For example, the output voltage at the comparator-output 119 (CMP0 output) is sampled at time t1 as calibration signal CalN−2, sampled at time t2 as calibration signal CalN−1, and sampled at time t3 as calibration signal CalN. The input offset trim codes (CMPIcalcode in FIG. 4) based on the calibration signals CalN−2, CalN−1, and CalN are coupled correspondingly to the clocked comparator 110 between time t1+τ and time t2+τ, between time t2+τ and time t3+τ, and between time t3+τ and time t4+τ.

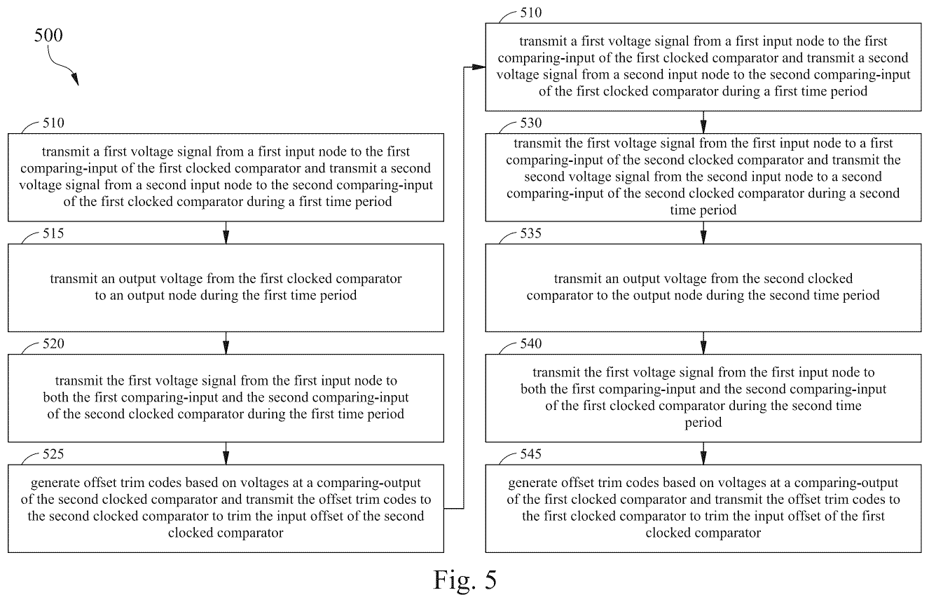

FIG. 5 is a flowchart of method 500 of operating a voltage comparator circuit, in accordance with some embodiments. The sequence in which the operations of method 500 are depicted in FIG. 5 is for illustration only; the operations of method 500 are capable of being executed in sequences that differ from that depicted in FIG. 5. It is understood that additional operations may be performed before, during, and/or after the method 500 depicted in FIG. 5, and that some other processes may only be briefly described herein. The operations of the method 500 are described by referring to the waveforms in FIG. 4 and the voltage comparator circuit 100 in FIG. 1.

In operation 510 of method 500, a first voltage signal is transmitted from a first input node to the first comparing-input of the first clocked comparator and a second voltage signal is transmitted from a second input node to the second comparing-input of the first clocked comparator during a first time period. In the example embodiments as shown in FIG. 1 and FIG. 4, the voltage signal V_{REF} is transmitted from the first input node 101 to the first comparing-input 111 of the clocked comparator 110, and the voltage signal V_{FB} is transmitted from the second input node 102 to the second comparing-input 112 of the clocked comparator 110 through the multiplexer 130, during the time period from time t3+τ to time t7+τ.

In operation 515 of method 500, an output voltage is transmitted from the first clocked comparator to an output node during the first time period. In the example embodiments as shown in FIG. 1 and FIG. 4, an output voltage at the comparator-output 119 of the clocked comparator 110 is transmitted to the output node 109 through the multiplexer 160, during the time period from time t3+τ to time t7+τ.

In operation 520 of method 500, the first voltage signal is transmitted from the first input node to both the first comparing-input and the second comparing-input of the second clocked comparator during the first time period. In the example embodiments as shown in FIG. 1 and FIG. 4, the voltage signal V_{REF} is transmitted from the first input node 101 to both the first comparing-input 121 and the second comparing-input 122 of the clocked comparator 120, during the time period from time t3+τ to time t7+τ.

In operation 525 of method 500, offset trim codes are generated based on voltages at a comparing-output of the second clocked comparator and the offset trim codes are transmitted to the second clocked comparator to trim the input offset of the second clocked comparator. In the example embodiments as shown in FIG. 1 and FIG. 4, offset trim codes are generated based on the calibration signals Cal1, Cal2, Cal3, and CalN sampled from the comparator-output 129 of the second clocked comparator 120, and the offset trim codes are transmitted to the offset-trim input 125 to trim the input offset of the clocked comparator 120.

In operation 530 of method 500, the first voltage signal is transmitted from the first input node to the first comparing-input of the second clocked comparator and the second voltage signal is transmitted from the second input node to the second comparing-input of the second clocked comparator during a second time period. In the example embodiments as shown in FIG. 1 and FIG. 4, the voltage signal V_{REF} is transmitted from the first input node 101 to the first comparing-input 121 of the clocked comparator 120, and the voltage signal V_{FB} is transmitted from the second input node 102 to the second comparing-input 122 of the clocked comparator 120 through the multiplexer 130, during the time period before time t3+τ or after time t7+τ.

In operation 535 of method 500, an output voltage is transmitted from the second clocked comparator to the output node during the second time period. In the example embodiments as shown in FIG. 1 and FIG. 4, an output voltage at the comparator-output 129 of the clocked comparator 120 is transmitted to the output node 109 through the multiplexer 160, during the time period before time t3+τ or after time t7+τ.

In operation 540 of method 500, the first voltage signal is transmitted from the first input node to both the first comparing-input and the second comparing-input of the first clocked comparator during the second time period. In the example embodiments as shown in FIG. 1 and FIG. 4, the voltage signal V_{REF} is transmitted from the first input node 101 to both the first comparing-input 111 and the second comparing-input 112 of the clocked comparator 110, during the time period before time t3+τ or after time t7+τ.

In operation 545 of method 500, offset trim codes are generated based on voltages at a comparing-output of the first clocked comparator and the offset trim codes are transmitted to the first clocked comparator to trim the input offset of the first clocked comparator. In the example embodiments as shown in FIG. 1 and FIG. 4, offset trim codes are generated based on the calibration signals CalN−2, CalN−1, and CalN and the offset trim codes are transmitted the offset-trim input 115 to trim the input offset of the clocked comparator 110.

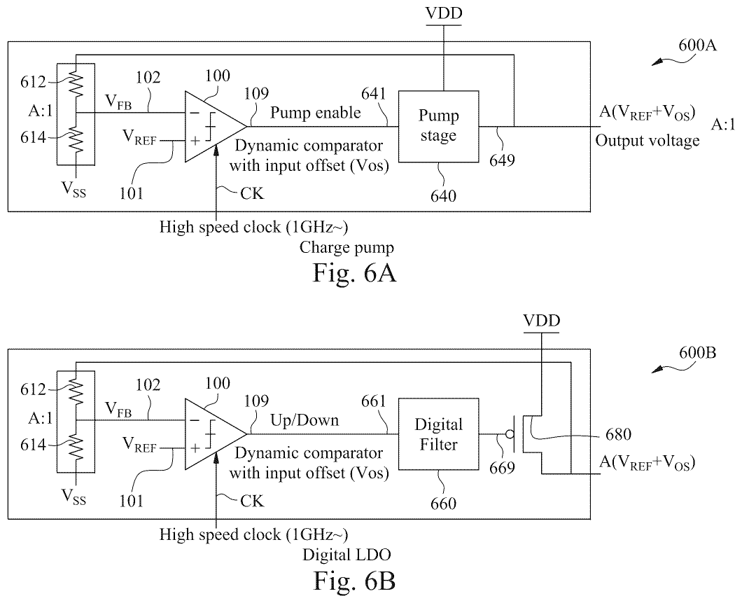

Two example applications of the voltage comparator circuit 100 of FIG. 1 are described with respect to FIGS. 6A-6B. FIG. 6A is a circuit diagram of a charge pump 600A having a voltage comparator circuit which has the input offset trimmed during operation, in accordance with some embodiments. FIG. 6B is a circuit diagram of a digital low dropout (LDO) voltage regulator 600B having a voltage comparator circuit which has the input offset trimmed during operation, in accordance with some embodiments.

In each of FIG. 6A and FIG. 6B, the non-inverting input node 101 of the voltage comparator circuit 100 is configured to receive a reference voltage V_{REF}, and the inverting input node 102 of the voltage comparator circuit 100 is configured to receive a feedback voltage V_{FB}. The feedback voltage V_{FB} is generated by a voltage divider having resistors 612 and 614 serially connected between an output voltage (which is to be regulated) and the supply voltage VSS. Furthermore, the timing of various operations in the voltage comparator circuit 100 are synchronized with the clock signal CK. In one specific example implementation, the clock signal CK has a frequency of about 1 GHz.

In FIG. 6A, the output node 109 of the voltage comparator circuit 100 is connected to an input 641 of a pump stage 640. The supply voltages provided to the pump stage 640 include the supply voltage VDD. The output voltage generated at the output 649 of the pump stage 640 is coupled to the voltage divider having the resistors 612 and 614, and the feedback voltage V_{FB} induced by the output voltage is coupled to the inverting input node 102 of the voltage comparator circuit 100.

In FIG. 6B, the output node 109 of the voltage comparator circuit 100 is connected to an input 661 of a digital filter 660. The output 669 of the digital filter 660 is connected to the gate terminal of a transistor 680. The source terminal of the transistor 680 is connected to the supply voltage VDD. The output voltage generated at the drain terminal of the transistor 680 is coupled to the voltage divider having the resistors 612 and 614, and the feedback voltage V_{FB} induced by the output voltage is coupled to the inverting input node 102 of the voltage comparator circuit 100.

In FIGS. 6A-6B, as the voltage comparator circuit 100 is operating with the 100% duty cycle to compare the voltage difference between the feedback voltage V_{FB} and the reference voltage V_{REF}, each of the charge pump 600A and the digital low dropout voltage regulator 600B has an improved performance as compared with alternative implementations in which the voltage comparator circuits used for implementing charge pumps or LDO regulators do not have 100% duty cycle.

An aspect of the present disclosure relates to an integrated circuit. The integrated circuit includes a first multiplexer having a first multiplexing-input connected to a first input node and having a second multiplexing-input connected to a second input node; a second multiplexer having a first multiplexing-input connected to the first input node and having a second multiplexing-input connected to the second input node, a first clocked comparator having a first comparing-input connected to the first input node and having a second comparing-input coupled to an output of the first multiplexer, a second clocked comparator having a first comparing-input connected to the first input node and having a second comparing-input coupled to an output of the second multiplexer, and a third multiplexer having a first multiplexing-input connected to a comparator-output of the first clocked comparator and having a second multiplexing-input connected to a comparator-output of the second clocked comparator.

Another aspect of the present disclosure relates to a method. The method includes transmitting a first voltage signal from a first input node to a first comparing-input of a first clocked comparator while transmitting a second voltage signal from a second input node to a second comparing-input of the first clocked comparator through a first multiplexer during a first time period; transmitting the first voltage signal from the first input node to a first comparing-input of a second clocked comparator while transmitting the second voltage signal from the second input node to a second comparing-input of the second clocked comparator through a second multiplexer during a second time period, and transmitting an output voltage from the first clocked comparator to an output node during the first time period and transmitting an output voltage from the second clocked comparator to the output node during the second time period.

Another aspect of the present disclosure still relates to an integrated circuit. The integrated circuit includes a first input node configured to carry a first voltage signal; a second input node configured to carry a second voltage signal; a first multiplexer and a second multiplexer, where each of the first multiplexer and the second multiplexer has a first multiplexing-input configured to receive the first voltage signal from the first input node and has a second multiplexing-input configured to receive the second voltage signal from the second input node. The circuit also includes a first clocked comparator and a second clocked comparator, where each of the first clocked comparator and the second clocked comparator has a first comparing-input configured to receive the first voltage signal from the first input node, where the first clocked comparator has a second comparing-input configured to receive the second voltage signal from the first multiplexer during a first time period and configured to receive the first voltage signal from the first multiplexer during a second time period, and where the second clocked comparator has a second comparing-input configured to receive the first voltage signal from the second multiplexer during a first time period and configured to receive the second voltage signal from the second multiplexer during a second time period.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a first multiplexer having a first multiplexing-input connected to a first input node and having a second multiplexing-input connected to a second input node;
a second multiplexer having a first multiplexing-input connected to the first input node and having a second multiplexing-input connected to the second input node;
a first clocked comparator having a first comparing-input connected to the first input node and having a second comparing-input coupled to an output of the first multiplexer;
a second clocked comparator having a first comparing-input connected to the first input node and having a second comparing-input coupled to an output of the second multiplexer; and
a third multiplexer having a first multiplexing-input connected to a comparator-output of the first clocked comparator and having a second multiplexing-input connected to a comparator-output of the second clocked comparator.

2. The integrated circuit of claim 1, wherein:
the first multiplexer is configured to be controlled with a first selection signal; and
the second multiplexer is configured to be controlled with a second selection signal which is synchronized with the first selection signal.

3. The integrated circuit of claim 2, wherein:
the third multiplexer is configured to be controlled with a third selection signal which is synchronized with both the first selection signal and the second selection signal.

4. The integrated circuit of claim 2, wherein the second selection signal is a logical complement of the first selection signal.

5. The integrated circuit of claim 2, wherein
the third multiplexer is configured to be controlled with a third selection signal which is either the first selection signal or the second selection signal.

6. The integrated circuit of claim 1, further comprising:
an offset control circuit having a first input port connected to the comparator-output of the first clocked comparator and having a second input port connected to the comparator-output of the second clocked comparator.

7. The integrated circuit of claim 6, wherein the offset control circuit comprises:
a first output port connected to an offset-trim input of the first clocked comparator; and
a second output port connected to an offset-trim input of the second clocked comparator.

8. The integrated circuit of claim 6, wherein:
the first clocked comparator is configured to receive a first clock signal; and
the second clocked comparator is configured to receive a second clock signal which is synchronized with the first clock signal.

9. The integrated circuit of claim 8, wherein:
the offset control circuit is configured to receive a third clock signal which is synchronized with both the first clock signal and the second clock signal.

10. The integrated circuit of claim 8, wherein:
the offset control circuit is configured to receive a third clock signal, wherein each the first clock signal and the second clock signal, and the third clock signal is generated from a common clock signal.

11. A method comprising:
transmitting a first voltage signal from a first input node to a first comparing-input of a first clocked comparator while transmitting a second voltage signal from a second input node to a second comparing-input of the first clocked comparator through a first multiplexer during a first time period;
transmitting the first voltage signal from the first input node to a first comparing-input of a second clocked comparator while transmitting the second voltage signal from the second input node to a second comparing-input of the second clocked comparator through a second multiplexer during a second time period; and
transmitting an output voltage from the first clocked comparator to an output node during the first time period and transmitting an output voltage from the second clocked comparator to the output node during the second time period.

12. The method of claim 11, further comprising:
transmitting a voltage at the first comparing-input of the second clocked comparator to the second comparing-input of the second clocked comparator through the second multiplexer during the first time period.

13. The method of claim 11, further comprising:
transmitting a voltage at the first comparing-input of the first clocked comparator to the second comparing-input of the first clocked comparator through the first multiplexer during the second time period.

14. The method of claim 11, further comprising:
trimming an input offset of the second clocked comparator during the first time period; and
trimming an input offset of the first clocked comparator during the second time period.

15. The method of claim 11, further comprising:
generating an offset trim code based on a voltage at a comparing-output of the second clocked comparator during the first time period; and
transmitting the offset trim code to the second clocked comparator to adjust the input offset of the second clocked comparator during the first time period.

16. The method of claim 11, further comprising:
generating an offset trim code based on a voltage at a comparing-output of the first clocked comparator during the second time period; and
transmitting the offset trim code to the first clocked comparator to adjust the input offset of the first clocked comparator during the second time period.

17. An integrated circuit comprising:
a first input node configured to carry a first voltage signal;
a second input node configured to carry a second voltage signal;
a first multiplexer and a second multiplexer, wherein each of the first multiplexer and the second multiplexer has a first multiplexing-input configured to receive the first voltage signal from the first input node and has a second multiplexing-input configured to receive the second voltage signal from the second input node; and
a first clocked comparator and a second clocked comparator, wherein each of the first clocked comparator and the second clocked comparator has a first comparing-input configured to receive the first voltage signal from the first input node, wherein the first clocked comparator has a second comparing-input configured to receive the second voltage signal from the first multiplexer during a first time period and configured to receive the first voltage signal from the first multiplexer during a second time period, and wherein the second clocked comparator has a second comparing-input configured to receive the first voltage signal from the second multiplexer during the first time period and configured to receive the second voltage signal from the second multiplexer during the second time period.

18. The integrated circuit of claim 17, further comprising:
a third multiplexer having a first multiplexing-input connected to a comparator-output of the first clocked comparator and having a second multiplexing-input connected to a comparator-output of the second clocked comparator.

19. The integrated circuit of claim 17, further comprising:
an offset control circuit having a first input port connected to a comparator-output of the first clocked comparator and having a second input port connected to a comparator-output of the second clocked comparator.

20. The integrated circuit of claim 19, wherein the offset control circuit comprises:
a first output port connected to an offset-trim input of the first clocked comparator; and
a second output port connected to an offset-trim input of the second clocked comparator.
